(19) United States
(12) Patent Application Publication
(10) Pub. No.: US 2024/0020197 A1
(43) Pub. Date: Jan. 18, 2024

(54) TECHNIQUES FOR ERROR DETECTION IN ANALOG COMPUTE-IN-MEMORY

(71) Applicant: Intel Corporation, Santa Clara, CA (US)

(72) Inventors: Wei WU, Portland, OR (US); Hechen WANG, Portland, OR (US)

(21) Appl. No.: 18/372,525

(22) Filed: Sep. 25, 2023

(51) Int. Cl. G06F 11/10; G06F 11/07; G06F 17/16

(52) U.S. Cl. CPC G06F 11/1068; G06F 11/076; G06F 17/16

(57) ABSTRACT

Circuitry for a compute-in-memory (CiM) circuit or structure arranged to detect bit errors in a group of memory cells based on a summation of binary 1's included in at least one weight matrix stored to the group of memory cells, a parity value stored to another group of memory cells and a comparison of the summation or the parity value to an expected value.

### TECHNICAL FIELD

Descriptions are generally related to error detection in analog compute-in-memory (CiM) circuit using a summation-based error correction code (ECC).

### BACKGROUND

Computer artificial intelligence (AI) has been built on machine learning, particularly using deep learning techniques. With deep learning, a computing system organized as a neural network computes a statistical likelihood of a match of input data with prior computed data. A neural network refers to a plurality of interconnected processing nodes that enable the analysis of data to compare an input to “trained” data. Trained data refers to computational analysis of properties of known data to develop models to use to compare input data. An example of an application of AI and data training is found in object recognition, where a system analyzes the properties of many (e.g., thousands or more) of images to determine patterns that can be used to perform statistical analysis to identify an input object such as a person's face.

Neural networks compute “weights” to perform computations on new data (an input data “word”). Neural networks use multiple layers of computational nodes, where deeper layers perform computations based on results of computations performed by higher layers. Machine learning currently relies on the computation of dot-products and absolute difference of vectors, typically computed with multiply and accumulate (MAC) operations performed on the parameters, input data and weights. Because these large and deep neural networks may include many such data elements, these data elements are typically stored in a memory separate from processing elements that perform the MAC operations.

Due to the computation and comparison of many different data elements, machine learning is extremely compute intensive. Also, the computation of operations within a processor are typically orders of magnitude faster than the transfer of data between the processor and memory resources used to store the data. Placing all the data closer to the processor in caches is prohibitively expensive for the great majority of practical systems due to the need for large data capacities of close proximity caches. Thus, the transfer of data when the data is stored in a memory separate from processing elements becomes a major bottleneck for AI computations. As the data sets increase in size, the time and power/energy a computing system uses for moving data between separately located memory and processing elements can end up being multiples of the time and power used to actually perform AI computations.

Some architectures (e.g., non-Von Neumann computation architectures) may employ CiM techniques to bypass von Neumann bottleneck” data transfer issues and execute convolutional neural network (CNN) as well as deep neural network (DNN) applications. The development of such architectures may be challenging in digital domains since MAC operation units of such architectures are too large to be squeezed into high-density Manhattan style memory arrays. For example, the MAC operation units may be magnitudes of order larger than corresponding memory arrays. For example, in a 4-bit digital system, a digital MAC unit may include 800 transistors, while a 4-bit Static random-access memory (SRAM) cell typically contains 24 transistors. Such an unbalanced transistor ratio makes it difficult, if not impossible to efficiently fuse the SRAM with the MAC unit. Thus, von-Neumann architectures can be employed such that memory units are physically separated from processing units. The data is serially fetched from the storage layer by layer, which results in a great latency and energy overhead.

### BRIEF DESCRIPTION OF THE DRAWINGS

FIG. 1 illustrates an example multiplier architecture.

FIG. 2 illustrates an example CiM structure.

FIG. 3 illustrates an example summation check logic.

FIG. 4 illustrates an example first summation check scheme.

FIG. 5 illustrates an example second summation check scheme.

FIG. 6 illustrates an example matching logic.

FIG. 7 illustrates error examples data or parity bits.

FIG. 8 illustrates example coverage for a summation-based ECC.

FIG. 9 illustrates an example first ECC word configuration and floor plan.

FIG. 10 illustrates an example second ECC word configuration and floor plan.

FIG. 11 illustrates an example third ECC word configuration and floor plan.

FIG. 12 illustrates an example first computing system.

FIG. 13 illustrates an example semiconductor apparatus.

FIG. 14 illustrates an example processor core.

FIG. 15 illustrates an example second computing system.

### DETAILED DESCRIPTION

In an era of artificial intelligence, computation is more data-intensive, consumes high energy, demands a high level of performance and requires more storage. It can be extremely challenging to fulfill these requirements/demands using conventional architectures and technologies. Analog CiM is starting to gain momentum due to a potential for higher levels of energy to area efficiency compared to conventional digital counterparts. Advantages of analog computing have been demonstrated in many fields especially in the areas of neural networks, edge processing, Fast Fourier transform (FFT), etc.

Similar to conventional memory architectures, analog CiM architectures can also suffer from various run-time faults that are sometimes due to process, voltage, temperature (PVT) uncertainty. A majority of current analog CiM architecture designs focus on power and performance, but rarely give sufficient consideration for data reliability. Data reliability can be critical for analog CiM architectures deployed in multi-bit representation systems.

SRAM reliability can be seriously affected by space radiation. Error correction codes (ECCs) represent one method to detect and correct data values maintained in a CiM architecture or structure from soft errors that can be caused by space radiation. Current ECC solutions are a “near-memory” not truly “in-memory” solutions for error mitigation for an analog CiM architecture or structure. These current ECC solutions are a “near-memory solution because post-computation signals are processed after an analog-digital-converter (ADC) converts analog signals to digital signals. Errors in the data maintained in an SRAM memory cell may not be detected after ADC conversion. A traditional ECC decoder can be comprised of a large number of XOR gates.

There are many difficulties to put a conventional ECC logic block or circuitry for use with a CiM architecture or structure. Conventional ECC logic blocks can be too large and too slow for use in a CiM architecture or structure. Also, conventional ECC logic blocks are digitally based and not analog based and are typically designed for large chunks of data (e.g., 64b or 256b). As a result, for at least some CiM architectures, error corrections have been intentionally neglected. Without error correction or detection in an analog CiM architecture or structure, increasing error rates are likely given that increasingly more bits are being stored in individual memory cells of analog CiM architectures or structures.

As described in more details below, this disclosure describes methods to enable error detection that is “in-memory” for an analog CiM architecture or structure to monitor for faults in an analog domain without digitalization. The methods include counting a total number of 1's in data stored to analog CiM memory cells (e.g., summation of individual digits) and store the summation in binary in a parallel capacitor structure. A summation value is then stored in parity bits in a C-2C capacitor ladder structure. Bit flips (e.g., caused by soft errors) could cause a sum comparison of the summation with the parity value to not match or fail and could trigger an error detection alarm.

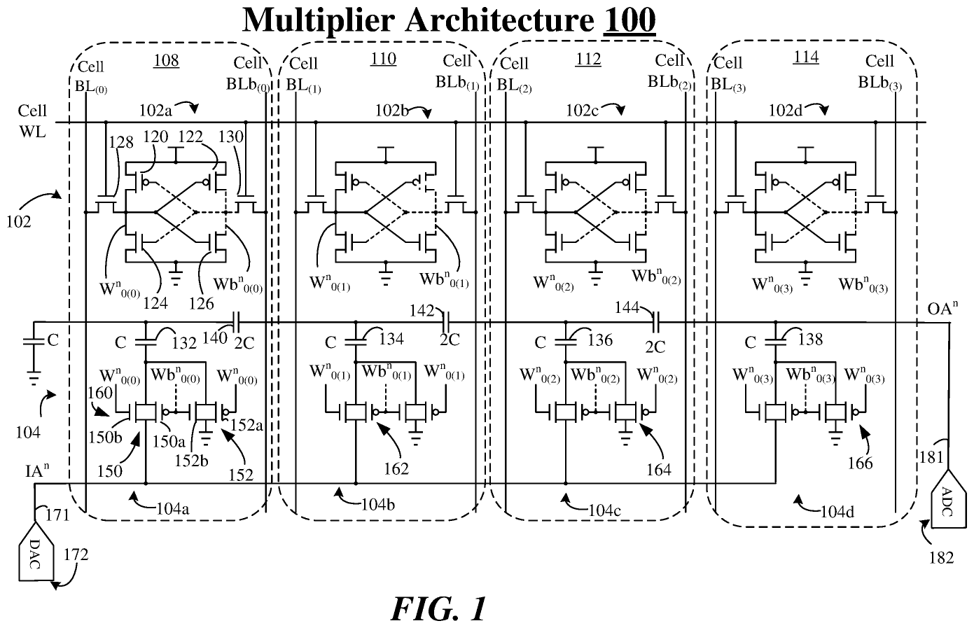

FIG. 1 illustrates an example multiplier architecture 100. In some examples, multiplier architecture 100 can represent a portion of a practical and efficient in-memory computing architecture that includes an integrated MAC unit and memory cell (which can be referred to as an arithmetic memory cell). The arithmetic memory cell employs analog computing methods so that a number of transistors of the integrated MAC unit is similar to a number of transistors of the memory cell (e.g., the transistors are a same order of magnitude) to reduce compute latency. For example, a neural network can be represented as a structure that is a graph of neuron layers flowing from one to the next. The outputs of one layer of neurons are the inputs of the next. To perform these calculations, a variety of matrix-vector, matrix-matrix, and tensor operations are required, which are themselves comprised of many MAC operations. Indeed, there are so many of these MAC operations in a neural network, that such operations may dominate other types of computations (e.g., the Rectified Linear Unit (ReLU) activation and pooling functions). Therefore, the MAC operation is enhanced by reducing data fetches from long term storage and distal memories separated from the MAC unit. Thus, examples described in this disclosure merge the MAC unit with the memory as shown in multiplier architecture 100 to reduce longer latency data movement and fetching (e.g., for neural network applications) Also, analog-based mixed-signal computing that is more efficient than digital (e.g., at low precision), can be employed to reduce data movement costs as compared to conventional digital processors and to also circumvent energy-hungry analog to digital conversions.

As shown in FIG. 1, multiplier architecture 100 includes memory array 102 (which is coupled to one or more unillustrated substrates) and a C-2C based multiplier 104 (which can also be coupled to the one or more substrates) and the memory array 102. C-2C based multiplier 104 shown in FIG. 1 can be configured as a C-2C ladder that includes a series of capacitors C segmented into 4 branches, each branch can be considered a separate multiple shown in FIG. 1 as 304a, 304b, 304c, 304d. As shown in FIG. 1, respective branch/multipliers 304a, 304b, 304c and 304d include respective switches 160, 162, 164 and 166. Also, as shown in FIG. 1, respective branch/multipliers 304a, 304b, 304c and 304d include respective capacitors 132, 134, 136 and 138 that each have a one unit capacitance and include respective capacitors 140, 142, 144 and 146 that each have a two unit capacitance. In some examples, capacitors included in multiplier architecture 100 can be configured as an overlapping structure of passive metal-oxide-metal (MOM) capacitor situated above an SRAM cell active region.

In some examples, multipliers 104a, 104b, 104c, 104d can be configured to receive digital signals from memory array 102, execute a multibit computation operation with the plurality of capacitors 132/140, 134/142, 136/144 and 138/146 based on the digital signals and output a first analog signal OAⁿ that is sent towards an analog-digital-converter (ADC) 182 (via a CiM bit line (BL) 181 based on the multibit computation operation. OAⁿ can also be referred to as a output voltage (V out) The multibit computation operation can be further based on an input analog signal IAⁿ received via a CiM word line (WL) 171 that originated from a digital-analog-converter (DAC) 172 and can also be referred to as a reference voltage (V REF). Memory array 102, as shown in FIG. 1, includes first, second, third and fourth memory cells 102a, 102b, 102c, 102d. Input activation signal IAⁿ originated from DAC 172 via CiM WL 171 can be provided from a first layer of the neural network, while in-memory multiplier architecture 100 can represent a second layer of the neural network. For example, the C-2C based multiplier 104 may be applied to any layer of a neural network. The superscript “n” indicates that it is applied to (operates on) the nth layer of the neural network. As such, the C-2C based multiplier 104 (e.g., an in-memory multiplier) represents the nth layer of the neural network. IAⁿ can represent an input activation signal at the nth layer, and can be the output of the previous layer (layer n−1). OAⁿ can be the output signal at the nth layer, and it will be fed into the next layer (layer n+1) which can be arranged in similar architecture as shown in FIG. 1 for multiplier architecture 100. DAC 172, CiM WL 171, ADC 182 and CiM BL 181 are described in more detail below in relation to an example CiM structure.

According to some examples, as shown in FIG. 1, each of the plurality of multipliers 104a, 104b, 104c, 104d can be associated with a respective one of memory cells 102a, 102b, 102c, 102d. For example, a first arithmetic memory cell 108 includes multiplier 104a and memory cell 102a such that multiplier 104a receives digital signals (e.g., weights) from the memory cell 102a. A second arithmetic memory cell 110 includes multiplier 304b and memory cell 102b such that multiplier 304b receives digital signals (e.g., weights) from memory cell 102b. A third arithmetic memory cell 112 includes multiplier 104c and memory cell 102c such that multiplier 104c receives digital signals (e.g., weights) from memory cell 102c. A fourth arithmetic memory cell 114 includes multiplier 104d and memory cell 302d such that multiplier 104d receives digital signals (e.g., weights) from memory cell 102d.

In some examples, the weights W, obtained during a neural network training progress and can be preloaded in the network, can be stored in a digital format for information fidelity and storage robustness. With respect to the input activation (which is the analog input signal IAⁿ) and the output activation (which is the analog output signal OAⁿ), the priority can be shifted to the dynamic range and response latency. That is, analog scalars of analog signals, with an inherent unlimited number of bits and continuous time-step, outperforms other storage candidates Thus, multiplier architecture 100 (e.g., a neural network) receives the analog input signal IAⁿ (e.g., an analog waveform) as an input and stores digital bits as its weight storage to enhance neural network application performance, design and power usage. In some examples, memory cells 102a, 102b, 102c, 102d can be arranged to store different bits of a same multibit weight.

According to some examples, arithmetic memory cell 108 of arithmetic memory cell 108, 110, 112, 114 is discussed below as an example for brevity, but it will be understood that arithmetic memory cells 110, 112, 114 are similarly configured to arithmetic memory cell 108. For these examples, memory cell 102a stores a first digital bit of a weight in a digital format. That is, memory cell 102a includes first, second, third and fourth transistors 120, 122, 124 and 126. The combination of the first, second, third and fourth transistors 120, 122, 124 and 126 store and output the first digital bit of the weight. For example, the first, second, third and fourth transistors 120, 122, 124 and 126 output weight signals Wⁿ₀₍₀₎ and W^{bn}₀₍₀₎ which represent a digital bit of the weight. The conductors that transmit the signal weight Wⁿ₀₍₀₎ are represented in FIG. 1 as an unbroken line and the conductors that conduct the weight signal W^{bn}₀₍₀₎ are represented in FIG. 1 as a broken line for clarity. The fifth and sixth transistors 128, 130 can selectively conduct electrical signals from a cell bit line (BL) from among BL₍₀₎ and BL_{b(0)} in response to an electrical signal of a cell word line (WL) meeting a threshold (e.g., voltage of cell WL exceeds a voltage threshold). That is, the electrical signal of the cell WL is applied to gates of the fifth and sixth transistors 128, 130 and the electrical signals of BL₍₀₎ and BL_{b(0)} are applied to sources of the fifth and sixth transistors 128, 130.

In some examples, signals Wⁿ₀₍₀₎ and W^{bn}₀₍₀₎ from memory cell 302a can be provided to multiplier 304a and as shown schematically by the locations of the weight signals Wⁿ₀₍₀₎ and W^{bn}₀₍₀₎ (which represent the digital bit). Multiplier 304a includes capacitors 132, 140, where capacitor 132 can include a capacitance 2C that is double a capacitance C of capacitor 140. Switch 160 of multiplier 304a can be formed by a first pair of transistors 150 and a second pair of transistors 152. The first pair of transistors 150 can include transistors 150a, 150b and selectively couple to input analog signal IAⁿ (e.g., input activation) to capacitor 132 based on the weight signals Wⁿ₀₍₀₎, W^{bn}₀₍₀₎. The second pair of transistors 152 can include transistors 152a, 152b that selectively couple capacitor 132 to ground based on the weight signals Wⁿ₀₍₀₎, W^{bn}₀₍₀₎. Thus, capacitor 132 can be selectively coupled between ground and input analog signal IAⁿ based on weight signals Wⁿ₀₍₀₎, W^{bn}₀₍₀₎. That is, one of the first and second pairs of transistors 150, 152 can be in an ON state to electrically conduct signals, while the other of the first and second pairs of transistors 150, 152 can be in an OFF state to electrically disconnect terminals. For example in a first state, the first pair of transistors 150 can be in an ON state to electrically connect capacitor 132 to input analog signal IAⁿ while the second pair of transistors 152 is in an OFF state to electrically disconnect capacitor 132 from ground. In a second state, the second pair of transistors 152 can be in an ON state to electrically connect capacitor 132 to the ground while the first pair of transistors 150 is in an OFF state to electrically disconnect the capacitor 132 from input analog signal IAⁿ. Thus, capacitor 132 can be selectively electrically coupled to ground or input analog signal IAⁿ based on the weight signals Wⁿ₀₍₀₎ and W^{bn}₀₍₀₎.

As mentioned above, arithmetic memory cells 110, 112, 114 can be formed similarly to arithmetic memory cell 108. That is, a cell BL from among BL₍₁₎, BL_{b(1)} and the cell WL can selectively control memory cell 102b to generate and output the weight signals Wⁿ₀₍₁₎ and W^{bn}₀₍₁₎ (which represents a second bit of the weight). Multiplier 104b includes capacitor 134 that can be selectively electrically coupled to ground or input analog signal IAⁿ through switch 162 and based on the weight signals Wⁿ₀₍₁₎ and W^{bn}₀₍₁₎ generated by memory cell 102b.

Similarly, a cell BL from among BL₍₂₎, BL_{b(2)} and the cell WL can selectively control the third memory cell 102c to generate and output weight signals Wⁿ₀₍₂₎ and W^{bn}₀₍₂₎ (which represents a second bit of the weight). Multiplier 104c includes capacitor 136 that can be selectively electrically coupled to ground or input analog signal IAⁿ through switch 164 based on weight signals Wⁿ₀₍₂₎ and W^{bn}₀₍₂₎ generated by memory cell 102b. Likewise, a cell BL from among BL₍₃₎, BL_{b(3)} and the cell WL can selectively control memory cell 102d to generate and output weight signals Wⁿ₀₍₃₎ and W^{bn}₀₍₃₎ (which represents a fourth bit of the weight). Multiplier 104d includes a capacitor 138 that can selectively electrically couple to ground or input analog signal IAⁿ through switch 166 based on weight signals Wⁿ₀₍₃₎ and Wⁿ₀₍₃₎ generated by memory cell 102b. Thus, each of the first-fourth arithmetic memory cells 108, 110, 112, 114 provides an output based on the same input activation signal IAⁿ but also on a different bit of the same weight.

According to some examples, the first-fourth arithmetic memory cells 108, 110, 112, 114 operate as a C-2C ladder multiplier. Connections between different branches of this C-2C ladder multiplier includes capacitors 140, 142, 144. The second, third and fourth multipliers 104b, 104c, 104d are respectively downstream of the first, second and third multipliers 104a, 104b, 104c. Thus, outputs from the first, second and third multipliers 104a, 104b, 104c and/or first, second and third arithmetic memory cells 108, 110, 112 are binary weighted through the capacitors 140, 142, 144. As shown in FIG. 1, the fourth arithmetic memory cell 114 does not include a capacitor at an output thereof since there is no arithmetic memory cell downstream of the fourth arithmetic memory cell 114. The product is then obtained at the output node at the end of the C-2C ladder. Multiplier architecture 100 can generate output analog signal OAⁿ, which corresponds to the below example equation 1. Example equation 1 is an example equation of an m-bit multiplier:

$$IA \times {\sum }_{i = 0}^{m - 1} {W}_{i} \times \frac{1}{{2}^{m - i}} \qquad Equation 1$$

In example equation 1, m+1 is equal to the number of bits of the weight. In this particular example, m is equal to three (m iterates from 0-3) since there are 4 weight bits as noted above. The “i” in example equation 1 corresponds to a position of a weight bit (again ranging from 0-3) such that Wᵢ is equal to the value of the bit at the position. It is worthwhile to note that example equation 1 can be applicable to any m-bit weight value. For example, if hypothetically the weight included more bits, more arithmetic memory cells may be added do the multiplier architecture 100 to process those added bits (in a 1-1 correspondence).

In some examples, multiplier architecture 100 employs a cell charge domain multiplication method by implementing a C-2C ladder for a type of digital-to-analog-conversion of bits of a weight maintained in memory cells. The C-2C ladder can be a capacitor network including capacitors 132, 134, 136, 138 having capacitance C, and capacitors 140, 142, 144 that have capacitance 2C. The capacitors 132, 134, 136, 138, 140, 142, 144 are shown in FIG. 1 as being segmented into branches and can provide low power analog voltage outputs such as OAⁿ to an ADC such as ADC 182.

According to some examples, memory array 102 and the C-2C based multiplier 104 can be disposed proximate to each other. For example, memory array 102 and the C-2C based multiplier 104 may be part of a same semiconductor package and/or in direct contact with each other. Moreover, memory array 102 can be an SRAM structure, but memory array 102 can also be readily modified to be of various memory structures (e.g., dynamic random-access memory, magnetoresistive random-access memory, phase-change memory, etc.) without modifying operation of the C-2C based multiplier 104 mentioned above.

As described in more detail below, a multiplier architecture such as the above-described multiplier architecture 100 can be included in a CiM structure as a node among a plurality of nodes in an array.

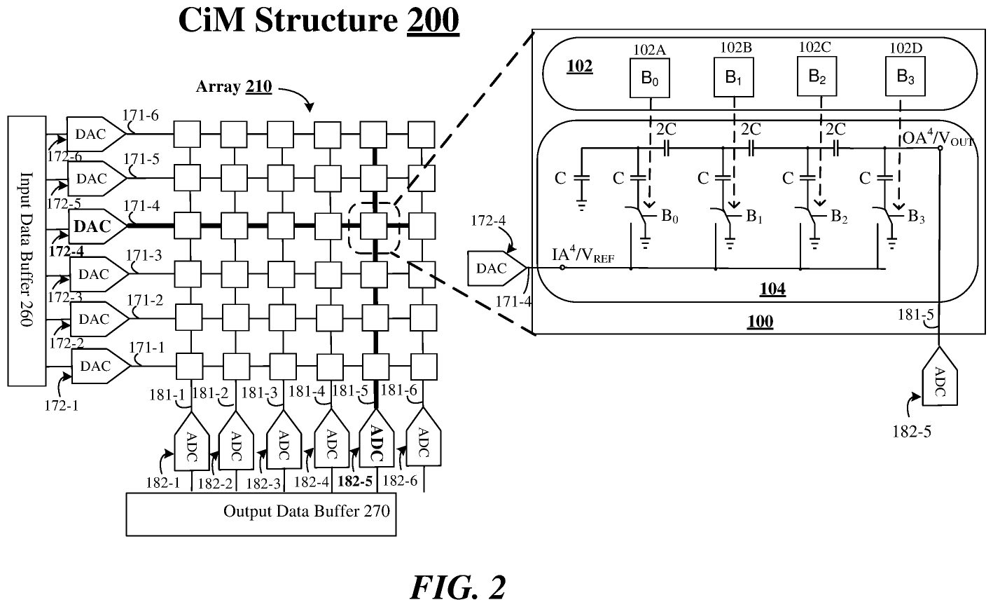

FIG. 2 illustrates an example CiM structure 200. According to some examples, as shown in FIG. 2, CiM structure 200 include an array 210 having a plurality of nodes that represent a complete tile structure. For these examples, input data obtained from input data buffer 260 can be converted to an analog input signal IA^{a}/V_{REF} by a DAC from among DACs 172-1 to 172-6 and then multiplied by 4-bit weight elements maintained at each node (e.g., maintained at memory cell 102) along a selected CiM WL from among CiM WLs 171-1 to 171-6. Computed analog outputs OAⁿ/V_{OUT} from the nodes along a CiM BL from among CiM BLs 181-181-6 can be tied together for summation in a charge domain. An ADC from among ADCs 182-1 to 182-6 can then convert the summation into a digital signal/value that is then stored to output data buffer 270.

For example CiM structure 200, an expanded view of a single node is depicted in FIG. 1 that shows a simplified representation of multiplier architecture 100. The simplified representation of multiplier architecture 100 indicates that an analog input signal IAⁿ can be received via a CiM WL 171-4 that was generated by DAC 172-4. A multiplication operation can be performed using 4-bit weight elements maintained in b₀, b₁, b₂ and b₃ to generate analog output OAⁿ. OAⁿ can then be sent via a CiM BL 181-5 for summation in a charge domain with other nodes along CiM BL 181-5 for eventual conversion of the summation by ADC 182-5 into a digital signal/value that can then be stored to output data buffer 270.

Examples are not limited to an array that includes nodes arranged in a 6×6 matrix as shown in FIG. 2. Also, examples are not limited to 4-bit weight elements maintained at each node. Also, examples are not limited to 6 DACs or 6 ADCs.

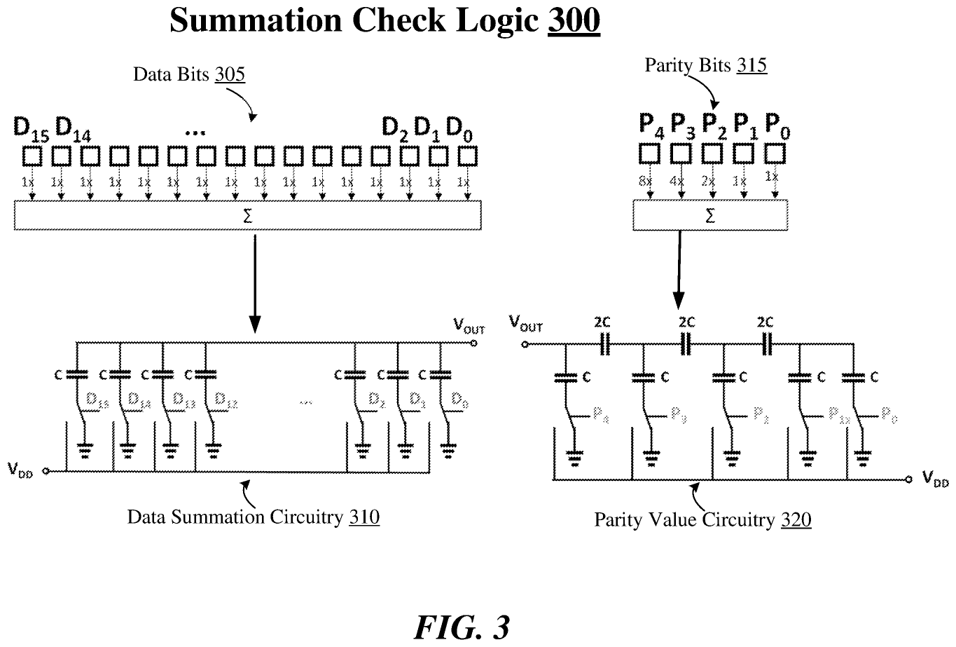

FIG. 3 illustrates an example summation check logic 300. In some examples, as shown in FIG. 3, data bits 305 can be encoded using data summation circuitry 310 and parity bits 315 can be encoded with parity value circuitry 320. Data bits 305 includes Do to D₁₅, where “D” represents a binary “1” or “0” for weight bits maintained in a group of SRAM memory cells such as memory cells 102a-d of memory array 102 shown in FIG. 1 or 2. Do to D₁₅, for example, can represent individual weight bits maintained in a group of 4 memory arrays 102 that includes a total of 16 bits. Parity bits 315 includes P₀ to P₄ that represent a 5-bit parity value to indicate a number of 1's expected to be included in Do to Dis. Parity bits 315 can also be a memory array similar to memory array 102, but includes an extra memory cell compared to the 4-bit memory arrays shown in FIG. 1 or 2. For these examples, the total number of expected 1's is based on a fixed weight matrix that can be preloaded to the group of SRAM memory cells.

According to some examples, the 16-bits included in data bits 305 and the 5-bits included in parity bits 315 is to cover parity values from 0 to 16, where the lower two bits (P₁ and P₀) are both least significant bits LSB (e.g., weight of 1). For example, a binary output of 11111=8+4+2+1+1=16 and a binary output of 11110=8+4+2+1+0=15. Since a total of 16 1's are possible in data bits 305, the additional parity bit is needed to indicate up to a value of 16.

In some examples, as shown in FIG. 3, data summation circuitry 310 is arranged as a parallel capacitor structure that outputs a V_{OUT} indicative of a summation of 1's included in data bits 305 stored in SRAM memory cells. The summation can range from 0 to 16. Also, parity value circuitry 320 is arranged as a C-2C capacitor ladder that can operate in similar manner to C-2C based multiplier 104 shown in FIGS. 1 and 2 to output a V_{OUT} indicative of a 5-bit parity value that has the lower two bits as LSB bits.

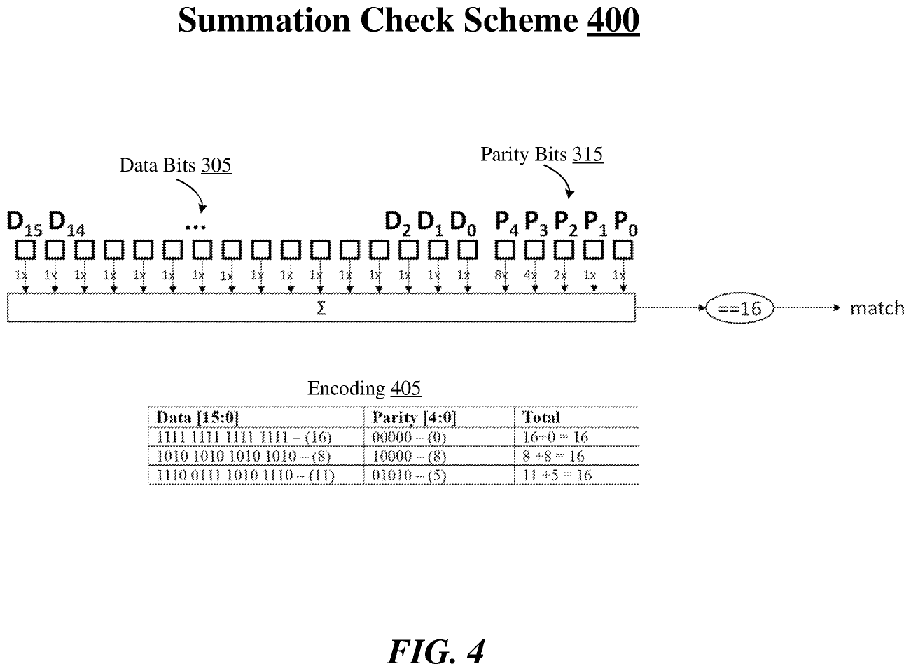

FIG. 4 illustrates a summation check scheme 400. According to some examples, encoding 405 indicates an example encoding for the 5 parity bits included in parity bits 315 to implement summation check scheme 400. For these examples, a total summation of data bits and a parity value equals an example fixed value of 16. So as shown in FIG. 4 for example encoding 405, if data bits 305 includes 16 1's, then parity bits P₄-P₀ included in parity bits 315 are encoded as 00000 having a binary value of 0. If 16 is added to 0 the total would equal 16. Also, the other 2 examples shown for encoding 405 depict an encoding based on 8 1's and 11 1's having respective parity values of 8 and 5 to both generate an expected summation of 16.

In some examples, as described more below, matching logic can include logic and/or circuitry to compare summation results to the fixed value of 16 to see if they match. If a match occurs than no errors are detected. If the summation results do not match the fixed value of 16, an error is detected. Detection of an error can cause mitigation actions to include, but not limited to reloading bit weights to the group of SRAM memory cells corresponding to Do to Dis of data bits 305 and/or reloading the encoded parity value to parity bits 315.

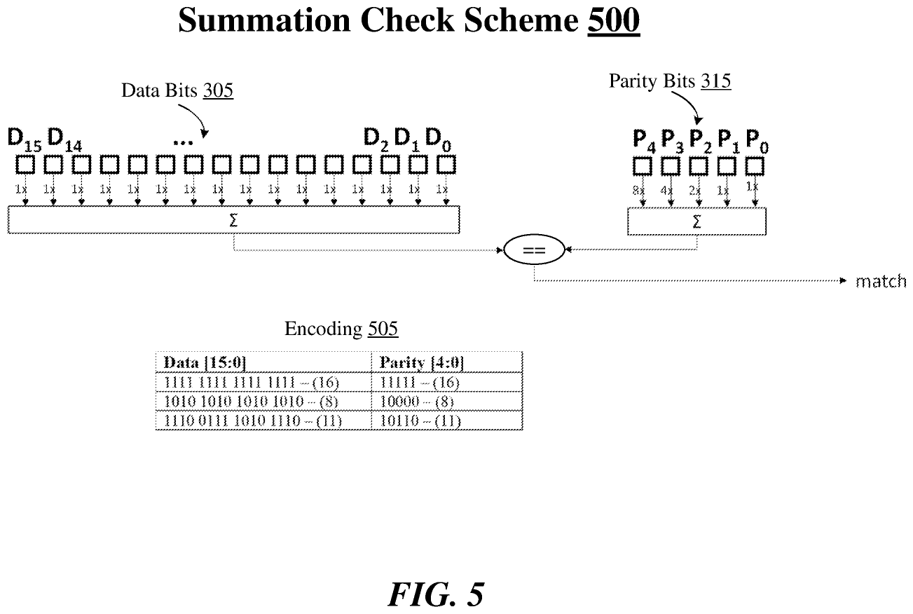

FIG. 5 illustrates a summation check scheme 500. According to some examples, encoding 505 indicates an example encoding for the 5 parity bits included in parity bits 315 to implement summation check scheme 500. For these examples, the summation of data bits equals a corresponding parity value. So as shown in FIG. 5 for example encoding 505, if data bits includes 16 1's, then parity bits P₄-P₀ included in parity bits 315 are encoded as 11111 having a binary value of 16. Also, the other 2 examples shown for encoding 505 depict an encoding based on 8 1's and 11 1's having respective parity values of 8 and 11.

In some examples, as described more below, matching logic can include logic and/or circuitry to compare summation results of bits Do to Dis included in data bits 305 to the parity binary value maintained in P₀ to P₄ included in parity bits 315 to see if they match (e.g., same Vₒᵤₜ). If a match occurs than no errors are detected. If the summation results of data bits 305 does not match (e.g., different V out) the parity value encoded in parity bits 315, an error is detected. Detection of an error can cause mitigation actions to include, but not limited to reloading bit weights to the group of SRAM memory cells corresponding to Do to Dis of data bits 305 and/or reloading the encoded parity value to parity bits 315.

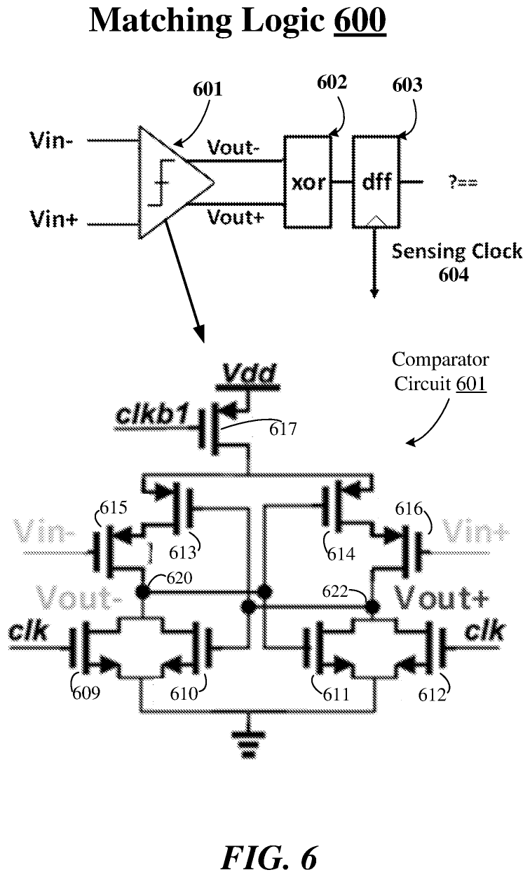

FIG. 6 illustrates an example matching logic 600. In some examples, as shown in FIG. 6, matching logic includes a comparator circuit 601, XOR logic 602, or a difference (dff) logic 603. For these example, dff logic 603 can determine a difference based on Vout− and Vout+ responsive to a sensing clock 604. Matching logic 600, in other words, serves as an analog comparator to compare a summation total (Vin−) with an expected value (Vin+). For examples, where the 16 data bits are protected with 5 parity bits, The expected value can depend on whether summation check scheme 400 (expected value of 16) or summation check scheme 500 (expected parity value matches number of 1's in data bits) is implemented.

According to some examples, as shown in FIG. 6, a more detailed view of comparator circuit 601 is shown that includes 9 transistors 609 to 617. Vin− activates transistor 613 and Vin+ activates 614 and Vout− can be sampled at node 620 and Vout+ can be sampled at node 622 to provide Vout− and Vout+.

In some examples, a 1-step comparison is implemented by matching logic 600 based on an equal-to-match method that outputs 1 or 0 if one input to comparator circuit 601 is greater or less that the other. For this 1-step comparison, a comparison time takes time to sense a difference and a T_{delay} can be inversely proportional to an input voltage difference. T_{delay} is shorter when the two input voltages (Vin−, Vin+) have a larger difference and much longer if the two input voltages have a larger difference. A careful selection can be needed to select a clock cycle time for sensing clock 604 such that the output voltage (Vout−, Vou+) is not settled when a clock signal sense by sensing clock 604 causes an output of XOR 602 for two substantially identical input voltages.

According to some examples, due to possible difficulties in selection of a T_{delay} due to process variations in manufacturing a CiM structure that includes matching logic 600, a 2-step comparison can be implemented. So instead of doing equal-to-match, the comparison is divided into two steps that provide two separate reference voltages for either matching logic 600 or summation check logic 300 (see FIG. 3).

A 2-step comparison method based on summation check scheme 400 (expected value of 16) includes a first step to check if all summations (e.g., Vin+) are greater than 15.5 via providing a first reference voltage (e.g., Vin−) to matching logic 600 and a second step to check if all summations are less than 16.5 via providing a second reference voltage to matching logic 600. If all summations are found to be greater than 15.5 but less than 16.5, a match is found.

In some examples, a 2-step comparison method based on summation check scheme 500 (expected data bits 1's equals parity value) includes adjusting a supply voltage at a parity side of summation check logic 300 (see FIG. 3). For these examples, instead of V_{DD}, 15/16 V_{DD} or 17/16V_{DD} or simply V_{DD+} and V_{DD-}. The first step of this 2-step comparison method is to replace V_{DD} shown in FIG. 3 for both data summation circuitry 310 and parity value circuitry 320 with V_{DD+} and a left wing of summation check logic 300 (data) should be less than a right wing of summation check logic 300 (parity). The second step is to change the supply voltage to V_{DD-} and the left wing should be greater than the right wing of summation check logic 300. Each step of this two-step method detects part of a failure case. In order to monitor summation values of the SRAM array from which data bits 305 are obtained, a toggling between the two steps is needed for this two-step method based on summation check scheme 500.

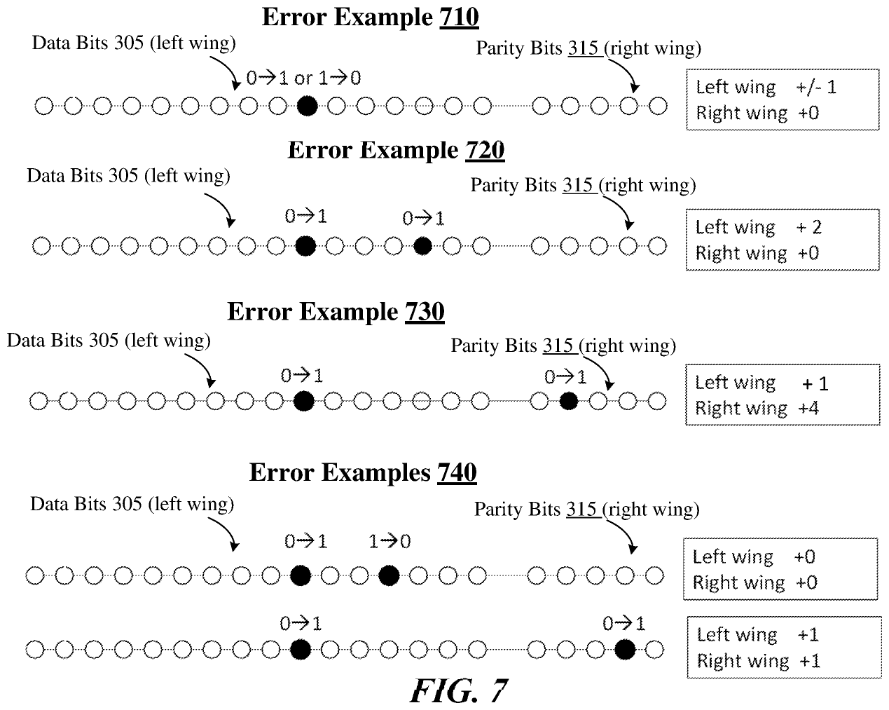

FIG. 7 illustrates various error examples 710, 720, 730 and 740. According to some examples, the error examples shown in FIG. 7 are based on summation check scheme 500, but a similar analysis could be applied to summation check scheme 400 as well. Error example 710 shows a single bit error that would be detected by a mismatch between sum of left wing and right wing due to a bit flip of the filled in circle of data bits 305 that can be a bit flip from a 0 to 1 or a 1 to 0 that causes the left wing to have a +/−1 summation value and the right wing having a +0 parity value change (no change). Error examples, 720 and 730 show 2-bit error examples. For error example 720, the 2-bit error occurs in data bits 305 by two bits flipping from 0 to 1 and this causes the left wing to have a +2 summation value and the right wing having a +0 parity value change (no change). For example 730, the 2-bit error occurs in both data bits 305 and parity bits 315 by a bit flipping from 0 to 1 in data bits 305 and another bit flipping from 0 to 1 in parity bits 315. The bit flip in data bits 305 causes the left wing to a have a +1 summation value and cause the right wing to have a +4 parity value change.

In some examples, error examples 740 shown in FIG. 7 provides an examples of where bit flips could cancel each other out and result in a match or balance between the left and right wings. For example, if a first bit on the left wing flips from 0 to 1 and a second bit on the left flips from 1 to 0. Also, if a bit on the left wing flips from 0 to 1 and an LSB bit on the right wing flips from 0 to 1. Both these examples included in error examples 740 would not result in detection of the bit flip errors.

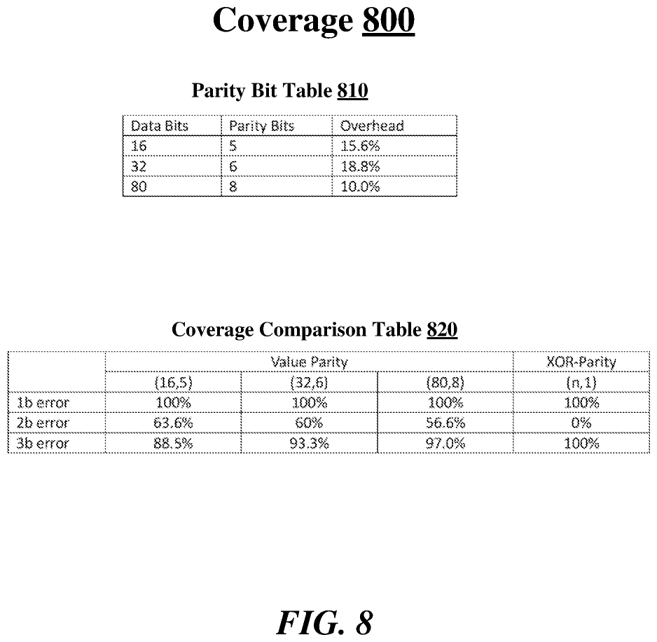

FIG. 8 illustrates an example coverage 800. In some examples, as shown in FIG. 8, coverage 800 includes a parity bit table 810 to indicate example number of parity bits needed to cover data bits of various lengths. For examples, as mentioned previously, 16 data bits would need 5 parity bits and the overhead needed to support would be about 15.6% greater than not providing any parity protection based on summation check schemes described above. 32 bits would need 6 with an added overhead of 18.8%. Since a higher ratio of parity bits to data bits is possible with 8 parity bits to cover 80 data bits, the added overhead of 10% is significantly less than the overhead needed to protect 16 or 32 bits.

According to some examples, coverage 800 also includes a coverage comparison table 820. As shown in FIG. 8, coverage comparison table 820 indicates a detection coverage of 16, 32 and 80 bits of data with 1/2/3b errors as compared to XOR-Parity ECC methods. As is shown in coverage comparison table 820, an ability to detect 2b errors can result in summation check schemes providing a better coverage than XOR-Parity ECC methods.

According to some examples, a weight matrix loaded to SRAM cells of a CiM structure can be fixed and doesn't change during computation operations. Therefore, a summation check scheme can also be static. An ECC word organization can be chosen that is easiest or best fit to a given floorplan for a CiM structure or any other considerations.

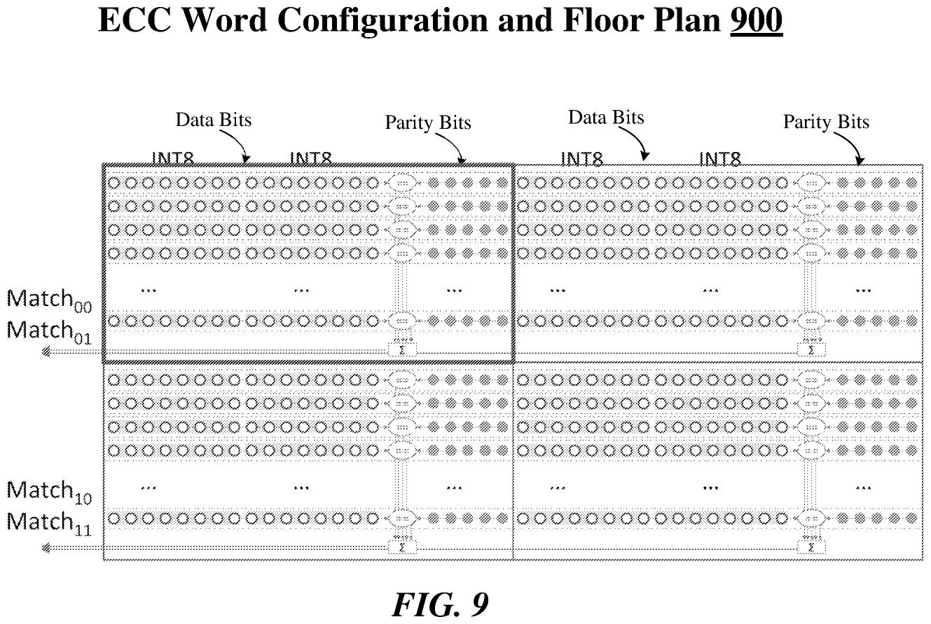

FIG. 9 illustrates an ECC word configuration and floor plan 900. ECC word configuration and floor plan 900 is an example of a horizontal ECC word organization that can apply a summation check along a horizontal word line where bits are logically related to at least one weight matrix. For example, as shown in FIG. 9, two 8-bit words that are side-by-side are combined as one ECC word. The two 8-bit words can represent one weight matrix or two separate weight matrixes. In other words, the summation value to indicate a number of 1's included in these two 8-bit words is compared to the parity values encoded in corresponding parity bits of the one ECC word.

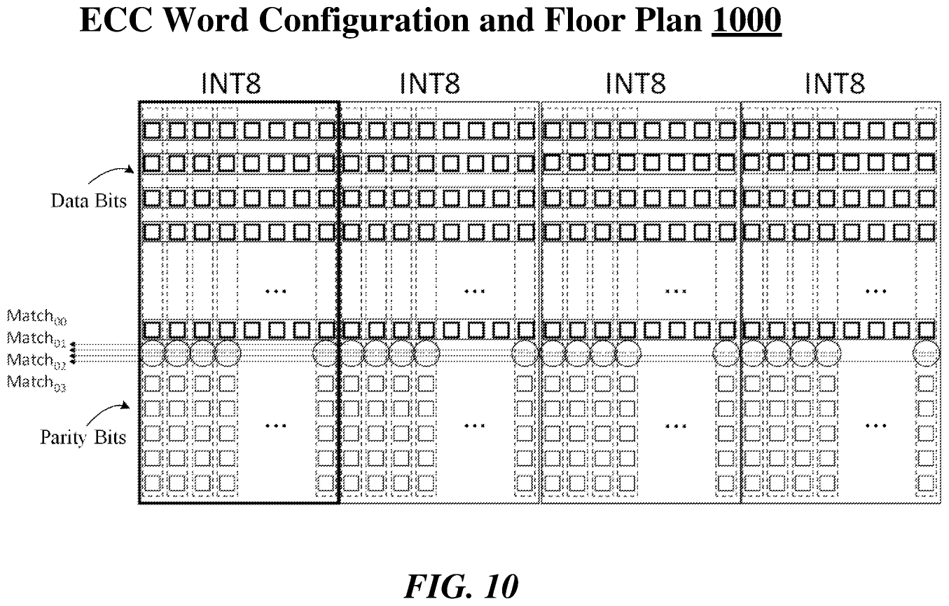

FIG. 10 illustrates an ECC word configuration and floor plan 1000. ECC word configuration and floor plan 1000 is an example of a vertical ECC word organization that can apply a summation check along a vertical bit line where data bits with a same significance but from 16 different logical words are combined together for each ECC code word. For example, 16 MSB data bits form one ECC word, and 16 LSB data bits form another ECC word.

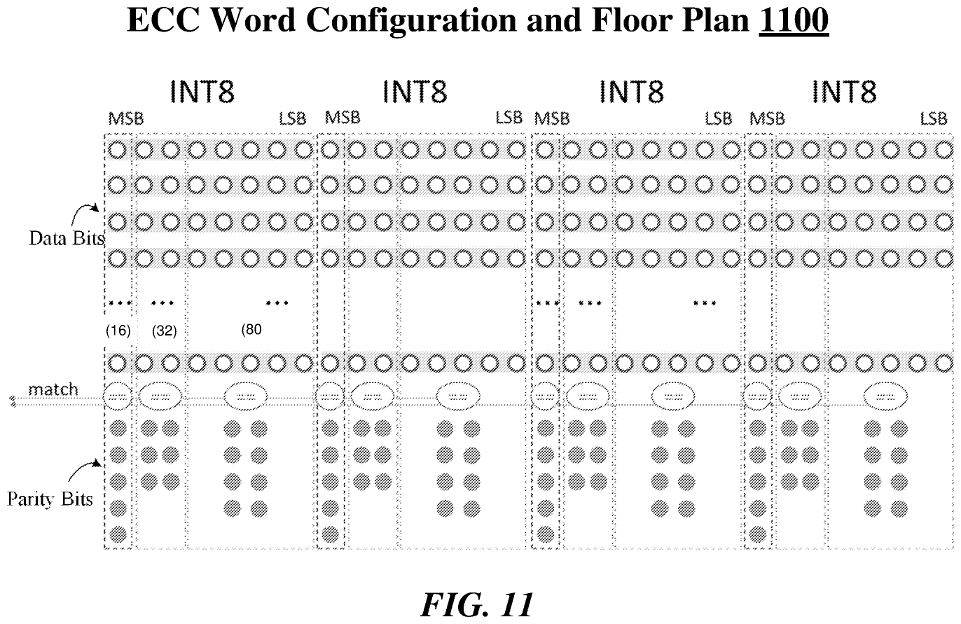

FIG. 11 illustrates an ECC word configuration and floor plan 1100. ECC word configuration and floor plan 1100 is an example of a vertical ECC word organization as mentioned above for ECC word configuration and floor plant 1000. However, data bits with higher significance (toward MSB) have a higher protection strength (more parity bits to protect fewer data bits). Also, data bits with lower significance (towards LSB) have a relatively lower protection strength (less parity bits to protect relatively more data bits). Overall, ECC word configuration and floor plan 1100 could be arranged such that a total number or check/parity bits needed to provide an acceptable level of error coverage can be less than ECC word configuration and floor plan 900 and/or 1000.

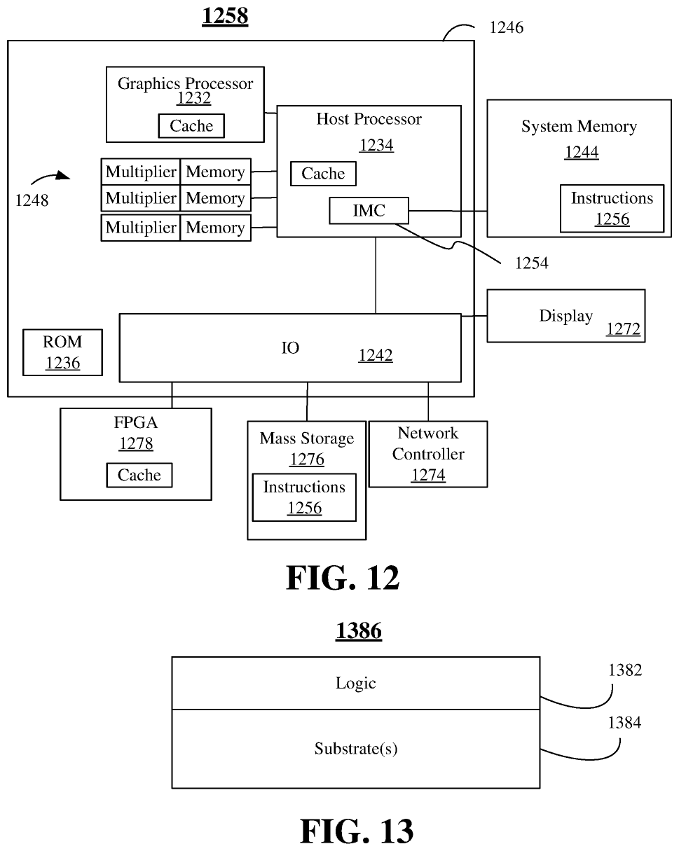

FIG. 12 illustrates an example a memory-efficient computing system 1258. The system 1258 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), etc., or any combination thereof. In the illustrated example, the system 1258 includes a host processor 1234 (e.g., CPU) having an integrated memory controller (IMC) 1254 that is coupled to a system memory 1244 with instructions 1256 that implement some aspects of the embodiments herein when executed.

The illustrated system 1258 also includes an input output (TO) module 1242 implemented together with the host processor 1234, a graphics processor 1232 (e.g., GPU), ROM 1236 and arithmetic memory cells 1248 on a semiconductor die 1246 as a system on chip (SoC). The illustrated IO module 1242 communicates with, for example, a display 1272 (e.g., touch screen, liquid crystal display/LCD, light emitting diode/LED display), a network controller 1274 (e.g., wired and/or wireless), FPGA 1278 and mass storage 1276 (e.g., hard disk drive/HDD, optical disk, solid state drive/SSD, flash memory) that may also include the instructions 1256. Furthermore, the SoC 1246 may further include processors (not shown) and/or arithmetic memory cells 1248 dedicated to artificial intelligence (AI) and/or neural network (NN) processing. For example, the system SoC 1246 may include vision processing units (VPUs), tensor processing units (TPUs) and/or other AI/NN-specific processors such as arithmetic memory cells 1248, etc. In some embodiments, any aspect of the embodiments described herein may be implemented in the processors and/or accelerators dedicated to AI and/or NN processing such as the arithmetic memory cells 1248, the graphics processor 1232 and/or the host processor 1234. The system 1258 may communicate with one or more edge nodes through the network controller 1274 to receive weight updates and activation signals.

It is worthwhile to note that the system 1258 and the arithmetic memory cells 1248 may implement in-memory multiplier architecture 100 (FIG. 1), CiM structure 200 (FIG. 2), summation check logic 300 (FIG. 3) or matching logic 600 (FIG. 6) already discussed. The illustrated computing system 1258 is therefore considered to implement new functionality and is performance-enhanced at least to the extent that it enables the computing system 1258 to execute operate on neural network data at a lower latency, reduced power and with greater area efficiency.

FIG. 13 illustrates an example semiconductor apparatus 1386 (e.g., chip, die, package). The illustrated apparatus 1386 includes one or more substrates 1384 (e.g., silicon, sapphire, gallium arsenide) and logic 1382 (e.g., transistor array and other integrated circuit/IC components) coupled to the substrate(s) 1384. In an embodiment, the apparatus 1386 is operated in an application development stage and the logic 1382 performs one or more aspects of the embodiments described herein, for example, in-memory multiplier architecture 100 (FIG. 1), CiM structure 200 (FIG. 2), summation check logic 300 (FIG. 3) or matching logic 600 (FIG. 6) already discussed. Thus, the logic 1382 receives, with a first plurality of multipliers of a multiply-accumulator (MAC), first digital signals from a memory array, where the first plurality of multipliers includes a plurality capacitors. The logic 1382 executes, with the first plurality of multipliers, multibit computation operations with the plurality of capacitors based on the first digital signals. The logic 1382 generates, with the first plurality of multipliers, a first analog signal based on the multibit computation operations. The logic 1382 may be implemented at least partly in configurable logic or fixed-functionality hardware logic. In one example, the logic 1382 includes transistor channel regions that are positioned (e.g., embedded) within the substrate(s) 1384. Thus, the interface between the logic 1382 and the substrate(s) 1384 may not be an abrupt junction. The logic 1382 may also be considered to include an epitaxial layer that is grown on an initial wafer of the substrate(s) 1384.

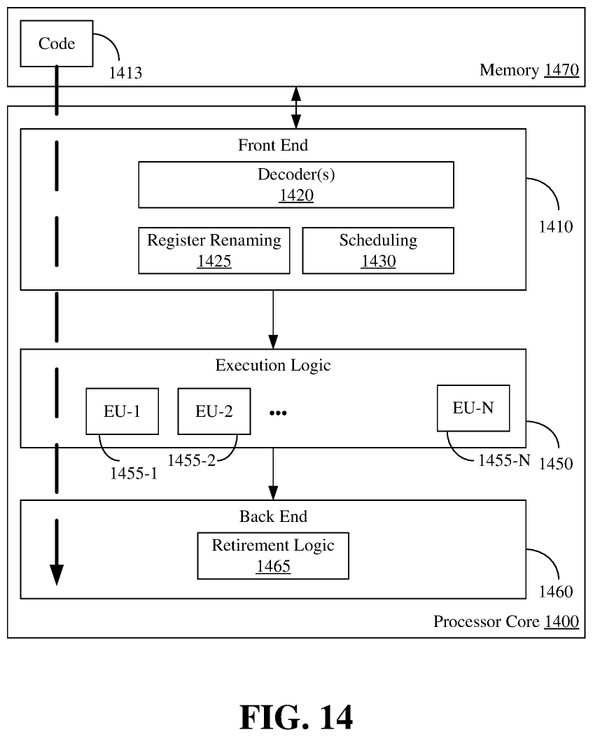

FIG. 14 illustrates an example processor core 1400 according to one embodiment. The processor core 1400 may be the core for any type of processor, such as a micro-processor, an embedded processor, a digital signal processor (DSP), a network processor, or other device to execute code. Although only one processor core 1400 is illustrated in FIG. 14, a processing element may alternatively include more than one of the processor core 1400 illustrated in FIG. 14. The processor core 1400 may be a single-threaded core or, for at least one embodiment, the processor core 1400 may be multithreaded in that it may include more than one hardware thread context (or “logical processor”) per core.

FIG. 14 also illustrates a memory 1470 coupled to the processor core 1400. The memory 1470 may be any of a wide variety of memories (including various layers of memory hierarchy) as are known or otherwise available to those of skill in the art. The memory 1470 may include one or more code 1413 instruction(s) to be executed by the processor core 1400, wherein the code 1413 may implement one or more aspects of the embodiments such as, for example, in-memory multiplier architecture 100 (FIG. 1), CiM structure 200 (FIG. 2), summation check logic 300 (FIG. 3) or matching logic 600 (FIG. 6) already discussed. The processor core 1400 follows a program sequence of instructions indicated by the code 1413. Each instruction may enter a front end portion 1410 and be processed by one or more decoders 1420. The decoder 1420 may generate as its output a micro operation such as a fixed width micro operation in a predefined format, or may generate other instructions, microinstructions, or control signals which reflect the original code instruction. The illustrated front end portion 1410 also includes register renaming logic 1425 and scheduling logic 1430, which generally allocate resources and queue the operation corresponding to the convert instruction for execution.

The processor core 1400 is shown including execution logic 1450 having a set of execution units 1455-1 through 1455-N. Some embodiments may include a number of execution units dedicated to specific functions or sets of functions. Other embodiments may include only one execution unit or one execution unit that can perform a particular function. The illustrated execution logic 1450 performs the operations specified by code instructions.

After completion of execution of the operations specified by the code instructions, back end logic 1460 retires the instructions of the code 1413. In one embodiment, the processor core 1400 allows out of order execution but requires in order retirement of instructions. Retirement logic 1465 may take a variety of forms as known to those of skill in the art (e.g., re-order buffers or the like). In this manner, the processor core 1400 is transformed during execution of the code 1413, at least in terms of the output generated by the decoder, the hardware registers and tables utilized by the register renaming logic 1425, and any registers (not shown) modified by the execution logic 1450.

Although not illustrated in FIG. 14, a processing element may include other elements on chip with the processor core 1400. For example, a processing element may include memory control logic along with the processor core 1400. The processing element may include I/O control logic and/or may include I/O control logic integrated with memory control logic. The processing element may also include one or more caches.

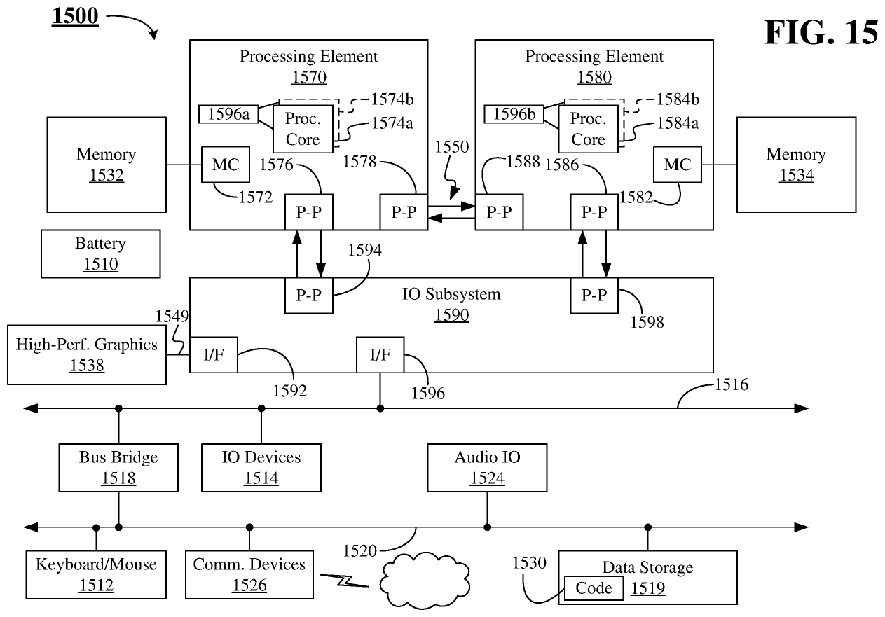

FIG. 15 illustrates an example computing system 1500 embodiment in accordance with an embodiment. Shown in FIG. 15 is a multiprocessor system 1500 that includes a first processing element 1570 and a second processing element 1580. While two processing elements 1570 and 1580 are shown, it is to be understood that an embodiment of the system 1500 may also include only one such processing element.

The system 1500 is illustrated as a point-to-point interconnect system, wherein the first processing element 1570 and the second processing element 1580 are coupled via a point-to-point interconnect 1550. It should be understood that any or all of the interconnects illustrated in FIG. 15 may be implemented as a multi-drop bus rather than point-to-point interconnect.

As shown in FIG. 15, each of processing elements 1570 and 1580 may be multicore processors, including first and second processor cores (i.e., processor cores 1574a and 1574b and processor cores 1584a and 1584b). Such cores 1574a, 1574b, 1584a, 1584b may be configured to execute instruction code in a manner similar to that discussed above in connection with FIG. 11.

Each processing element 1570, 1580 may include at least one shared cache 1596a, 1596b. The shared cache 1596a, 1596b may store data (e.g., instructions) that are utilized by one or more components of the processor, such as the cores 1574a, 1574b and 1584a, 1584b, respectively. For example, the shared cache 1596a, 1596b may locally cache data stored in a memory 1532, 1534 for faster access by components of the processor. In one or more embodiments, the shared cache 1596a, 1596b may include one or more mid-level caches, such as level 2 (L2), level 3 (L3), level 4 (L4), or other levels of cache, a last level cache (LLC), and/or combinations thereof.

While shown with only two processing elements 1570, 1580, it is to be understood that the scope of the embodiments are not so limited. In other embodiments, one or more additional processing elements may be present in a given processor. Alternatively, one or more of processing elements 1570, 1580 may be an element other than a processor, such as an accelerator or a field programmable gate array. For example, additional processing element(s) may include additional processors(s) that are the same as a first processor 1570, additional processor(s) that are heterogeneous or asymmetric to processor a first processor 1570, accelerators (such as, e.g., graphics accelerators or digital signal processing (DSP) units), field programmable gate arrays, or any other processing element. There can be a variety of differences between the processing elements 1570, 1580 in terms of a spectrum of metrics of merit including architectural, micro architectural, thermal, power consumption characteristics, and the like. These differences may effectively manifest themselves as asymmetry and heterogeneity amongst the processing elements 1570, 1580. For at least one embodiment, the various processing elements 1570, 1580 may reside in the same die package.

The first processing element 1570 may further include memory controller logic (MC) 1572 and point-to-point (P-P) interfaces 1576 and 1578. Similarly, the second processing element 1580 may include a MC 1582 and P-P interfaces 1586 and 1588. As shown in FIG. 15, MC's 1572 and 1582 couple the processors to respective memories, namely a memory 1532 and a memory 1534, which may be portions of main memory locally attached to the respective processors. While the MC 1572 and 1582 is illustrated as integrated into the processing elements 1570, 1580, for alternative embodiments the MC logic may be discrete logic outside the processing elements 1570, 1580 rather than integrated therein.

The first processing element 1570 and the second processing element 1580 may be coupled to an I/O subsystem 1590 via P-P interconnects 1576, 1586, respectively. As shown in FIG. 15, the I/O subsystem 1590 includes P-P interfaces 1594 and 1598. Furthermore, I/O subsystem 1590 includes an interface 1592 to couple I/O subsystem 1590 with a high performance graphics engine 1538. In one embodiment, bus 1549 may be used to couple the graphics engine 1538 to the I/O subsystem 1590. Alternately, a point-to-point interconnect may couple these components.

In turn, I/O subsystem 1590 may be coupled to a first bus 1516 via an interface 1596. In one embodiment, the first bus 1516 may be a Peripheral Component Interconnect (PCI) bus, or a bus such as a PCI Express bus or another third generation I/O interconnect bus, although the scope of the embodiments are not so limited.

As shown in FIG. 15, various I/O devices 1514 (e.g., biometric scanners, speakers, cameras, sensors) may be coupled to the first bus 1516, along with a bus bridge 1518 which may couple the first bus 1516 to a second bus 1520. In one embodiment, the second bus 1520 may be a low pin count (LPC) bus. Various devices may be coupled to the second bus 1520 including, for example, a keyboard/mouse 1512, communication device(s) 1526, and a data storage unit 1519 such as a disk drive or other mass storage device which may include code 1530, in one embodiment. The illustrated code 1530 may implement the one or more aspects of such as, for example, in-memory multiplier architecture 100 (FIG. 1), CiM structure 200 (FIG. 2), summation check logic 300 (FIG. 3) or matching logic 600 (FIG. 6) already discussed. Further, an audio I/O 1524 may be coupled to second bus 1520 and a battery 1510 may supply power to the computing system 1500.

Note that other embodiments are contemplated. For example, instead of the point-to-point architecture of FIG. 15, a system may implement a multi-drop bus or another such communication topology. Also, the elements of FIG. 15 may alternatively be partitioned using more or fewer integrated chips than shown in FIG. 15.

The following examples pertain to additional examples of technologies disclosed herein.

Example 1. An example apparatus can include first circuitry to generate a summation of binary 1's for a weight matrix stored in a first group of memory cells of a CiM structure. The apparatus can also include second circuitry to generate a parity value for parity bits stored to a second group of memory cells of the CiM structure. The apparatus can also include third circuitry to compare the summation of binary 1's and the parity value to an expected value and indicate whether one or more bit errors in the first or the second group of memory cells is detected based on the comparison.

Example 2. The apparatus of example 1, the first circuitry can be arranged as a parallel capacitor structure that outputs a first V_{OUT} indicative of the summation of binary 1's and the second circuitry can be arranged as a capacitor to 2 capacitor (C-2C) ladder to output a second V_{OUT} indicative of the parity value.

Example 3. The apparatus of example 2, the expected value can be based on a total number of memory cells included in the first group of memory cells. Each memory cell included in the first group of memory cell can be arranged to store a single bit. For this example, the third circuitry can include an analog comparator to compare a first input that includes a summation of the first V_{OUT} and the second V_{OUT} with a second input that includes a voltage representative of the expected value. Also, the analog comparator can output an indication of whether the first and the second input match, a match indication to indicate no detectable bit errors in the first or the second group of memory cells.

Example 4. The apparatus of example 2, the expected value can be based on a total number of memory cells included in the first group of memory cells, each memory cell included in the first group of memory cell can be arranged to store a single bit. Also, the third circuitry can include an analog comparator to compare the first V_{OUT} to the second V_{OUT} and output an indication of whether the first V_{OUT} and the second V_{OUT} match, a match indication to indicate no detectable bit errors in the first or the second group of memory cells.

Example 5. The apparatus of example 1, the second group of memory cells can include a number of memory cells to store a parity value in n bits, where n can represent a number of binary bits capable of indicating a range of parity values from 0 to a value equal to all memory cells of the first group of memory cells storing binary 1's.

Example 6. The apparatus of example 1, the first group of memory cells and the second group of memory cells can include SRAM cells.

Example 7. An example method can include determining a total number of binary 1's for a weight matrix stored in a first group of memory cells of a CiM structure. The method can also include determining a parity value for parity bits stored to a second group of memory cells of the CiM structure. The method can also include comparing the determined total number of binary 1's and the determined parity value to an expected value and detecting one or more bit errors in the first or the second group of memory cells based on the comparison.

Example 8. The method of example 7, the expected value can be based on a total number of memory cells included in the first group of memory cells, each memory cell included in the first group of memory cell arranged to store a single bit.

Example 9. The method of example 8, the determined total number of binary 1's and the determined parity value to the expected value can include comparing the determined total number of binary 1's to the expected value and comparing the determined parity value to the expected value, individually, wherein the expected value is based on an expected total number of binary 1's stored to the first memory cells.

Example 10. The method of example 9, comparing the determined total number of binary 1's and the determined parity value to the expected value can include combining the determined total number of binary 1's and the determined parity value and comparing the combined value to the expected value.

Example 11. The method of example 7, the second group of memory cells can include a number of memory cells to store a parity value in n bits, where n can represent a number of binary bits capable of indicating a range of parity values from 0 to a value equal to all memory cells of the first group of memory cells storing binary 1's.

Example 12. The method of example 7, determining the total number of binary 1's and determining the parity value can be done in an analog domain.

Example 13. The method of example 7, the first group of memory cells and the second group of memory cells can be SRAM cells.

Example 14. The method of example 8, the computational nodes of the first group and the second group can individually include SRAM bits cells that are arranged to store weight bits.

Example 15. An example at least one machine readable medium can include a plurality of instructions that in response to being executed by a system can cause the system to carry out a method according to any one of examples 7 to 14.

Example 16. An example apparatus can include means for performing the methods of any one of examples 7 to 14.

Example 17. An example CiM structure can include a first group of memory cells to maintain at least a portion of at least one weight matrix for use in computations. The CiM structure can also include a second group of memory cells to maintain parity bits associated with the at least a portion of at least one weight matrix. The CiM structure can also include first circuitry to generate a summation of binary 1's for the at least a portion of at least one weight matrix. The CiM structure can also include second circuitry to generate a parity value based on the parity bits. The CiM structure can also include third circuitry to compare the summation of binary 1's and the parity value to an expected value and indicate whether one or more bit errors in the first or the second group of memory cells is detected based on the comparison.

Example 18. The CiM structure of example 17, the first circuitry can be arranged as a parallel capacitor structure that outputs a first V_{OUT} indicative of the summation of binary 1's and the second circuitry can be arranged as a capacitor to 2 capacitor (C-2C) ladder to output a second V_{OUT} indicative of the parity value.

Example 19. The CiM structure of example 18, the expected value can be based on a total number of memory cells included in the first group of memory cells, each memory cell included in the first group of memory cell arranged to store a single bit. For this example, the third circuitry can be an analog comparator to compare a first input that includes a summation of the first V_{OUT} and the second V_{OUT} with a second input that includes a voltage representative of the expected value. The analog comparator can output an indication of whether the first and second inputs match, an indication to indicate no detectable bit errors in the first or the second group of memory cells.

Example 20. The CiM structure of example 18, the expected value can be based on a total number of memory cells included in the first group of memory cells, each memory cell included in the first group of memory cell arranged to store a single bit. The third circuitry can also include an analog comparator to compare the first V_{OUT} to the second V_{OUT} and output an indication of whether the first V_{OUT} and the second V_{OUT} match. A match indication can indicate no detectable bit errors in the first or the second group of memory cells.

Example 21. The CiM structure of example 17, the second group of memory cells can include a number of memory cells to store a parity value in n bits, where n can represent a number of binary bits capable of indicating a range of parity values from 0 to a value equal to all memory cells of the first group of memory cells storing binary 1's.

Example 22. The CiM structure of example 17, the first group of memory cells and the second group of memory cells can be SRAM cells.

Example 23. The CiM structure of example 17, the first group of memory cells can be situated along a same word line of the CiM structure and can be logically related to the at least one weight matrix.

Example 24. The CiM structure of example 17, the first group of memory cells can be situated along a same bit line and can have a same binary bit significance but are not logically related to the same at least one weight matrix.

Example 25. The CiM structure of example 25 can also include a third group of memory cells to maintain a second portion of the at least one weight matrix and also include a fourth group of memory cells to maintain parity bits associated with the second portion of the at least one weight matrix. The second portion can include least significant bits (LSBs) of the at least one weight matrix. The first group of memory cells can include most significant bits (MSBs) of the at least one weight matrix. For this example, the second group of memory cells can maintain a higher number of parity bits compared to parity bits maintained in the fourth group of memory cells.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

It is emphasized that the Abstract of the Disclosure is provided to comply with 37 C.F.R. Section 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. An apparatus comprising:
first circuitry to generate a summation of binary 1's for a weight matrix stored in a first group of memory cells of a compute-in-memory (CiM) structure;
second circuitry to generate a parity value for parity bits stored to a second group of memory cells of the CiM structure; and
third circuitry to compare the summation of binary 1's and the parity value to an expected value and indicate whether one or more bit errors in the first or the second group of memory cells is detected based on the comparison.

2. The apparatus of claim 1, wherein the first circuitry is arranged as a parallel capacitor structure that outputs a first V_{OUT} indicative of the summation of binary 1's and the second circuitry is arranged as a capacitor to 2 capacitor (C-2C) ladder to output a second V_{OUT} indicative of the parity value.

3. The apparatus of claim 2, the expected value is based on a total number of memory cells included in the first group of memory cells, each memory cell included in the first group of memory cell arranged to store a single bit, wherein the third circuitry comprises an analog comparator to compare a first input that includes a summation of the first V_{OUT} and the second V_{OUT} with a second input that includes a voltage representative of the expected value and, wherein the analog comparator outputs an indication of whether the first and the second input match, a match indication to indicate no detectable bit errors in the first or the second group of memory cells.

4. The apparatus of claim 2, the expected value is based on a total number of memory cells included in the first group of memory cells, each memory cell included in the first group of memory cell arranged to store a single bit, wherein the third circuitry comprises an analog comparator to:
compare the first V_{OUT} to the second V_{OUT}; and
output an indication of whether the first V_{OUT} and the second V_{OUT} match, a match indication to indicate no detectable bit errors in the first or the second group of memory cells.

5. The apparatus of claim 1, wherein the second group of memory cells includes a number of memory cells to store a parity value in n bits, where n represents a number of binary bits capable of indicating a range of parity values from 0 to a value equal to all memory cells of the first group of memory cells storing binary 1's.

6. The apparatus of claim 1, wherein the first group of memory cells and the second group of memory cells comprise static random access memory (SRAM) cells.

7. A method comprising:
determining a total number of binary 1's for a weight matrix stored in a first group of memory cells of a compute-in-memory (CiM) structure;
determining a parity value for parity bits stored to a second group of memory cells of the CiM structure;
comparing the determined total number of binary 1's and the determined parity value to an expected value; and
detecting one or more bit errors in the first or the second group of memory cells based on the comparison.

8. The method of claim 7, wherein the expected value is based on a total number of memory cells included in the first group of memory cells, each memory cell included in the first group of memory cell arranged to store a single bit.

9. The method of claim 8, comparing the determined total number of binary 1's and the determined parity value to the expected value comprises comparing the determined total number of binary 1's to the expected value and comparing the determined parity value to the expected value, individually, wherein the expected value is based on an expected total number of binary 1's stored to the first memory cells.

10. The method of claim 9, comparing the determined total number of binary 1's and the determined parity value to the expected value comprises combining the determined total number of binary 1's and the determined parity value and comparing the combined value to the expected value.

11. The method of claim 7, wherein the second group of memory cells includes a number of memory cells to store a parity value in n bits, where n represents a number of binary bits capable of indicating a range of parity values from 0 to a value equal to all memory cells of the first group of memory cells storing binary 1's.

12. A compute-in-memory structure, comprising:
a first group of memory cells to maintain at least a portion of at least one weight matrix for use in computations:
a second group of memory cells to maintain parity bits associated with the at least a portion of at least one weight matrix;
first circuitry to generate a summation of binary 1's for the at least a portion of at least one weight matrix;
second circuitry to generate a parity value based on the parity bits; and
third circuitry to compare the summation of binary 1's and the parity value to an expected value and indicate whether one or more bit errors in the first or the second group of memory cells is detected based on the comparison.

13. The compute-in-memory structure of claim 12, wherein the first circuitry is arranged as a parallel capacitor structure that outputs a first V_{OUT} indicative of the summation of binary 1's and the second circuitry is arranged as a capacitor to 2 capacitor (C-2C) ladder to output a second V_{OUT} indicative of the parity value.

14. The compute-in-memory structure of claim 13, the expected value is based on a total number of memory cells included in the first group of memory cells, each memory cell included in the first group of memory cell arranged to store a single bit, wherein the third circuitry comprises an analog comparator to compare a first input that includes a summation of the first V_{OUT} and the second V_{OUT} with a second input that includes a voltage representative of the expected value and, wherein the analog comparator outputs an indication of whether the first and second inputs match, a match indication to indicate no detectable bit errors in the first or the second group of memory cells.

15. The compute-in-memory structure of claim 13, the expected value is based on a total number of memory cells included in the first group of memory cells, each memory cell included in the first group of memory cell arranged to store a single bit, wherein the third circuitry comprises an analog comparator to:
compare the first V_{OUT} to the second V_{OUT}; and
output an indication of whether the first V_{OUT} and the second V_{OUT} match, a match indication to indicate no detectable bit errors in the first or the second group of memory cells.

16. The compute-in-memory structure of claim 12, wherein the second group of memory cells includes a number of memory cells to store a parity value in n bits, where n represents a number of binary bits capable of indicating a range of parity values from 0 to a value equal to all memory cells of the first group of memory cells storing binary 1's.

17. The compute-in-memory structure of claim 12, wherein the first group of memory cells and the second group of memory cells comprise static random access memory (SRAM) cells.

18. The compute-in-memory structure of claim 12, wherein the first group of memory cells are situated along a same word line of the compute-in-memory structure and are logically related to the at least one weight matrix.

19. The compute-in-memory structure of claim 12, wherein the first group of memory cells are situated along a same bit line and have a same binary bit significance but are not logically related to the same at least one weight matrix.

20. The compute-in-memory structure of claim 19, further comprising:
a third group of memory cells to maintain a second portion of the at least one weight matrix;
a fourth group of memory cells to maintain parity bits associated with the second portion of the at least one weight matrix, the second portion to include least significant bits (LSBs) of the at least one weight matrix; and
the first group of memory cells include most significant bits (MSBs) of the at least one weight matrix, wherein the second group of memory cells maintains a higher number of parity bits compared to parity bits maintained in the fourth group of memory cells.
